(19) United States
(12) Patent Application Publication
(10) Pub. No.: US 2015/0149108 A1
(43) Pub. Date: May 28, 2015

(54) METHOD AND SYSTEM FOR GENERATION OF A STATISTICALLY SPATIALLY-UNIFORM FIELD DISTRIBUTION INSIDE A REVERBERATION CHAMBER

(71) Applicant: Andréa Cozza, Paris (FR)

(72) Inventor: Andréa Cozza, Paris (FR)

(73) Assignee: SUPELEC, Gif Sur Yvette (FR)

(21) Appl. No.: 14/402,377

(22) PCT Filed: May 22, 2012
(86) PCT No.: PCT/IB2012/001607

§ 371 Date: Nov. 20, 2014

(51) Int. Cl. G01N 27/00; G01R 29/08

(52) U.S. Cl. CPC G01N 27/00; G01R 29/0821
USPC 702/124

(57) ABSTRACT

A method is provided for generation of statistically uniform field distribution inside a test volume of a reverberation chamber. The method includes:
generating complex independent and identically distributed random signals x,
filtering signals x through a passage matrix P according to a linear transformation in order to determine correlated excitation signals “a” by “a”=Px, P being a passage matrix determined from H a complex transfer function H between the test volume and the antennas; and P is constructed such that E=HPx where E is independent and identically distributed, and
generating the field E by applying simultaneously correlated excitation signals “a” to several antennas of the reverberation chamber.

The present invention relates to a method for generation of a statistically spatially-uniform field distribution inside the test volume of a reverberation chamber.

Reverberation chambers (RCs) have conquered a stable and important place among radiated test facilities, e.g. in EMC immunity/susceptibility tests. Among the many reasons for this outcome one may list their limited costs (as compared to anechoic chambers), compactness and the ability to reproduce test conditions that would be much more complex to enforce in anechoic chambers, such as submitting a Device Under Test (DUT) to a statistically uniform, isotropic, unpolarized volume distribution of electromagnetic field, high intensity electromagnetic fields or measuring the total radiated power for an antenna with no mechanical movement of the DUT or the field probes, thus quickly. Nevertheless, the frequency-span over which RCs properly work is strongly affected in its lower range by a limited number of available cavity modes. Indeed, the properties of an RC are based on the assumption that it can be regarded as an overmoded resonant cavity. As soon as this framework is no more valid, the lower the frequency the less effective the mode-stirring will be, leading to a stronger correlation between different field samples (in time and in space). The occurring of these limitations can be smoothed down by carefully designing the stirrers in order to have a higher impact on the cavity modes, and by extending the physical dimensions of the cavity as a last resort, a solution that obviously comes with a hefty price tag.

The lowest usable frequency (LUF) of a reverberation chamber (RC) is considered as the minimum frequency at which the cavity can still be regarded as overmoded and capable of generating a statistically uniform distribution of field amplitude over an extended region of space, referred to as test volume.

Actual researches on the functioning of RCs near their LUF have been mostly devoted to the description of their performances. Statistical analyses have been carried out, pointing out how the uniformity of the electromagnetic field is impaired by the lack of a densely populated modal domain, while at the same time the spatial correlation of the field increases, because of a reduced number of degrees of freedom.

Actual efforts to decrease the LUF can be divided into two groups: the first one dealing with modified cavity geometries, the second more concerned with the use of additional antennas. The first group includes such approaches as the use of larger mechanical stirrers or even additional wave diffractors mounted over the RC walls; the underlying idea is here to increase the ratio between the inner surface of the RC and its volume, thus enriching its modal density, see for example LR Arnaut “Operation of electromagnetic reverberation chambers with wave diffractors at relatively low frequencies”, Electromagnetic Compatibility, IEEE Transactions on Electromagnetic Compatibility, 2001, and W Petirsch et al., “Investigation of the field uniformity of a mode-stirred chamber using diffusers based on acoustic theory”, IEEE Transactions on Electromagnetic Compatibility, 1999.

It is important to notice that the effect of these measures leads to just a few percent points decrease of the LUF, rather than a radical change in the performances of the RC. Moreover, these solutions are mechanical ones, therefore inherently static and with no possibility to be reconfigured. On the other hand, the second group of solutions has provided several approaches here briefly recalled.

It is well-known that TEM modes are not affected by any cutting frequency and that they can be excited at frequencies as low as DC. These modes exist as soon as two electrically isolated conductors are present, as in usual two-wire lines. This idea can be exploited in order to excite fields at frequencies below the LUF of an RC, as proposed by J. Perini, L. S. Cohen, “Extending the operation of mode stirred chambers to low frequencies”, IEEE International Symposium on Electromagnetic Compatibility, 2002.

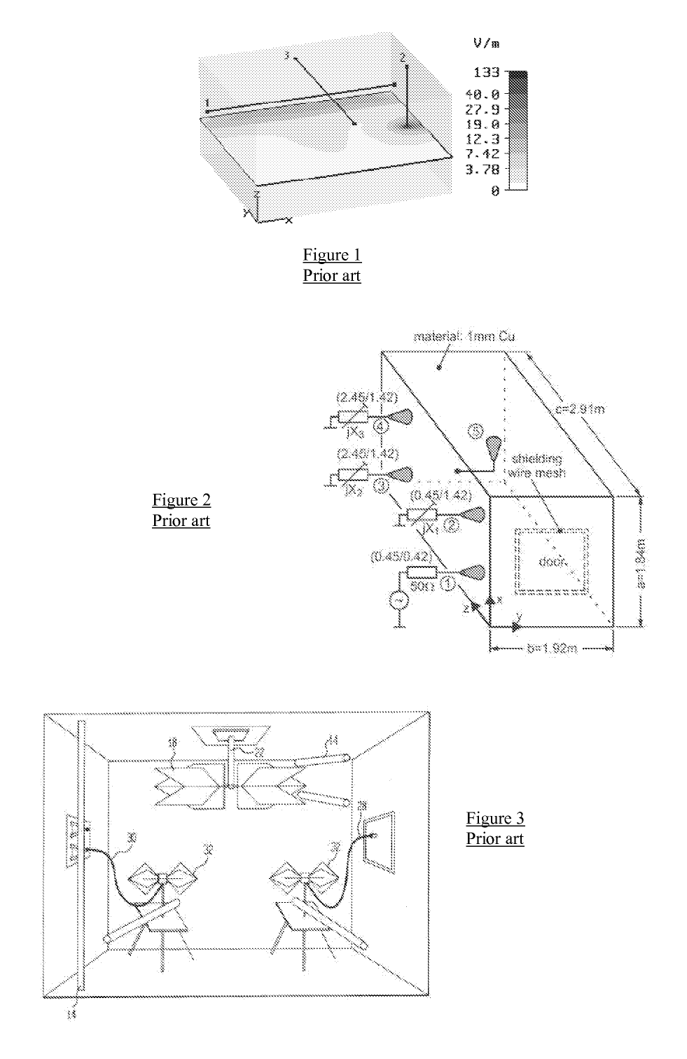

As shown in FIG. 1, several metallic conductors 1, 2, 3 are installed inside the RC, and potential differences are applied between these conductors and the RC shielding, thus exciting TEM modes. The obvious advantage is that the field distributions thus generated are not limited in frequency, and can therefore be applied to devices under test (DUTs) placed near the TEM lines. Unfortunately, this solution is not interesting for several reasons:
as known from electromagnetic theory, and clearly visible in FIG. 1.1, TEM modes present strongly localized field distributions. This is indeed the reason why they are so widely used in transmission lines as wave-guiding modes. Such property implies that the use of TEM modes for illuminating a DUT is not effective, since it requires the DUT to be at close range. At the same time, the localization of the energy means that TEM modes are ineffective in transferring power towards the DUT; this being one of the main advantages of RCs, in order to create high field levels, TEM modes would present performances similar to the use of an anechoic chamber. This conclusion is inevitable, since TEM modes are quasi-static distributions that cannot be made to resonate inside a finite-volume RC;
TEM modes present a longitudinal invariance in their transversal field distribution. In other words, the field distribution is the same along the TEM lines. The direct by-product of this fact is a strong correlation along the additional conductors; in fact, spatial correlation is opposed to the very idea of RCs, as it would reduce the “randomness” of the electromagnetic field illuminating a DUT. Similar conclusions can be drawn concerning the polarization of the field, again due to the static behaviour of the TEM modes.

Another recently proposed solution considers applying wire resonating antennas near the RC walls, designed as to resonate at certain fundamental frequencies closed to the desired frequency of testing. The antennas are terminated by time-varying loads, switched on and off according to a periodic pattern. In L. R. Arnaut, “Compound exponential distributions for undermoded reverberation chambers”, IEEE Transactions on Electromagnetic Compatibility, Vol. 44, No. 3, August 2002, this approach has been shown to lead to an enhanced spatial uniformity in the lower frequency range of the overmoded region. Nevertheless, although interesting, this approach cannot create new modes as it does not attempt to modify the boundary conditions over the RC walls. Neither a theoretical explanation of the working of this system, nor design rules, have yet been given by the authors, thus jeopardizing its adaptation to RCs of different dimensions. Furthermore, the use of specifically tuned antennas means that this solution is not easily reconfigurable, unless the antennas were physically changed when changing of frequency range.

Other solutions consist in additional antennas. This last class of solutions is the most promising, since intrinsically based on the idea of reconfigurability. Two configurations have been proposed so far; the first one, due to Voges et al., “Electrical mode stirring in reverberating chambers by reactively loaded antennas”, IEEE Transactions on Electromagnetic Compatibility, Vol. 49, Issue 4, November 2007, considers the use of antennas mounted on the walls of the RC, see FIG. 2.

Theses antennas are loaded by passive reactive circuits that are meant to modify the boundary conditions over the walls. The Authors proposed this solution as a new mode-stirring technique, as an alternative to existing ones. They did target neither the low-frequency range, nor the enhancement of the performance of the RC.

Indeed, the main problem with this solution is that, again, no physical interpretation is proposed, so that no design rules are available. Furthermore, the lack of active control means that the stirring ability of this solution is strongly impaired: the Authors report a one thousandth mode-stirring ability around the nominal frequency. They were not even able to explain the reason for the antenna choice, their positions, nor the value of the reactive loads. The second solution goes back to 1996, due to Goldblum, “Enhanced mode stirred test chamber”, U.S. Pat. No. 5,530,412, Jun. 25, 1996. The idea here is to exploit the high-level field that is typical in the near-field region of resonant antennas. This was implemented, as depicted in FIG. 3, by using transmitting antennas that radiates energy at frequencies at which the cavity does not resonate. Thus, the antenna excites a predominantly evanescent field distribution; the rods, placed at specific distances, resonate, and present a high-level field close to their surfaces. Therefore, by placing a DUT near them, it will be exposed to potentially very strong fields. Although interesting for high-power microwave tests, this technique is by no means a good solution to the original problem of the LUF. First of all, the energy is again strongly localized, although in this case the mechanisms are rather different from the case of TEM modes. Second, nearly all advantages of RCs are lost: the only one still subsisting is the possibility to attain high-level fields. But the randomness, statistical uniformity, unpolarized nature of the field distribution can no longer be attained, since, as for TEM lines, the field distribution is strongly correlated space-wise.

An object of the present invention is to overcome drawbacks of prior art by providing a new method for controlling the statistical properties of the electromagnetic field in a reverberation chamber. Another object of the present invention is the use of a reverberation chamber at low frequencies. The present invention also aims at reducing the cost of a system providing statistically uniform field inside a reverberation chamber.

In at least preferred embodiments, the present invention provides a method for generation of statistically uniform field distribution inside a test volume of a reverberation chamber by means of antennas, said method comprising:
generating complex independent and identically distributed random signals x,
filtering signals x through a passage matrix P according to a linear transformation in order to determine correlated excitation signals “a” by “a”=Px, P being a passage matrix determined from H which is a complex transfer function between the test volume and the antennas; and P is constructed such that E=HPx where E is independent and identically distributed,
   generating the field E by applying simultaneously correlated excitation signals “a” to several antennas of the reverberation chamber.

In other words, according to the invention, the field is determined as: E=Ha, “a” being the signals applied to the antennas to generate E. In order to obtain a statistically uniform field E distribution, which means E be independent identically distributed (iid), it is considered in the present invention that “a” is preferably a correlated excitation signals on the contrary to prior art where the excitation signals are independent identically distributed (iid). A new matrix P is introduced such that E=HPx, x being the iid signals. P is a squared matrix determined from H and by having as constraint the fact that E must be independent identically distributed (iid). H is the matrix of the transfer functions between the antenna input ports and the scalar field components of which the statistical intensity is to be controlled.

Preferably, each signal “a” is applied to respectively one antenna.

The method according to the invention permits to evenly excite all available modes, reducing the phenomenon of a dominant mode, thus enriching the modal scenario and ultimately improving the chances of generating a statistically uniform field.

As opposed to previous attempts at this approach [D. A. Hill, “Electronic mode stirring for reverberation chambers”, IEEE Transactions on Electromagnetic Compatibility, 1994], the random signals are correlated by means of a pre-conditioning filter, in order to increase the number of accessible degrees of freedom and optimize the covariance matrix of the field measured in the reverberation chamber. Excitation signals applied to the antennas are therefore not entirely random, and are based on a priori information on the response of the reverberation chamber. In the above reference, the excitation signals where entirely random, and led to no improvement with respect to other standard stirring techniques.

The present invention permits the use of reverberation chambers the dimensions of which are not sufficient to ensure a condition overmoded. In practice, the size of a reverberation chamber can be greatly reduced by a factor of up to five.

According to the invention, the pre-conditioning matrix P can be obtained from the following formulation:

P=\sqrt{(H^{H}H)⁻¹}, H^{H} being the Hermitian matrix of H

The method according to the invention is not trying to slightly modify the mode density by mechanically changing the boundary conditions of the reverberation chamber as proposed by Voges et al., but rather to control the boundary conditions in a much stronger way, with the aim to have an adaptive control over the reverberation chamber performances.

According to another embodiment of the invention, P may be obtained by numerical optimization of:

1=HPP^{H}H^{H} with a constraint c applied to P.

It is to be understood that all equalities “=” in the present invention are numerical equalities for which an exact solution or an approximate solution may be find.

The constraint may be defined as:

$$c = {max}_{P} \frac{{‖ E ‖}^{2}}{{‖ a ‖}^{2}} ,$$

where ∥a∥ is the norm of the vector of the excitations and ∥E∥ the norm of the field samples.

It is to be understood that the matrix P is determined by numerical optimization with the constraint that the field power be max with respect to the power delivered by the antennas. This constraint relates to maximum energy efficiency.

The constraint may also be:

$$c = {min}_{P} {σ}_{a}^{2} .$$

It is to be understood that the matrix P is determined by numerical optimization with the constraint to minimize the disparities of the antennas power. Advantageously, the power is equally divided between all antennas. The use of a distributed excitation allows use of smaller power sources, with a direct impact on the costs of testing means. This constraint relates to minimal amplitude dynamics in the excitations, i.e the variance in the amplitude of the excitation coefficients.

According to an embodiment of the invention, the method further comprises a calibration phase wherein several measuring points are defined, and for each measuring point measurements are determined using all antennas in order to determine the complex transfer function H.

Although this might appear as a step increasing the overall duration of the test, two points should be pondered: 1) the subsequent tests will require no mechanical displacement, thus faster; 2) this calibration phase is by no means comparable in complexity and time duration to the calibration of a standard mode-stirred reverberation chamber. Indeed, these measurements are carried out within a static configuration, so that it takes just a few minutes.

Advantageously for each measuring point, three field components are measured in a Cartesian reference to obtain statistically isotropic fields in the test volume. This implies three degrees of freedom.

In preferred embodiment, eight measuring points defining the test volume are used for the determination of the complex transfer function.

Preferably, the test volume is identified by the shape of a rectangular box. Its eight vertexes will be considered as to identify the test volume, which is considered as a region of space where the electric field can be regarded as a random variable characterized by the same probability law at any position. In other words, the statistics of the field are uniformly distributed within the test volume or stationary in space and time. The measurements are carried out by considering the three field components at the eight test-volume vertexes, arranging this data into a 24-entry vector.

Advantageously, the measurements are performed by means of phase sensitive probe. Since the optimal approach is based on a precise knowledge of the transfer function matrix H, a phase-sensitive field probe is preferably used.

According to the invention, at least two or four antennas are used. Preferably, as many antennas as measuring points are used.

According to an embodiment of the invention, the distance between antennas arranged in the reverberation chamber is superior or equal to λ/2, λ, being the wavelength of the working frequency.

According to the invention, all signals x are of the same frequency which is the working frequency.

According to an embodiment of the invention, the step of generating complex independent and identically distributed random signals x comprises a step of generating a master signal at the working frequency which is subsequently split into all signals x,
the step of filtering signals x through a passage matrix P comprises the step of applying amplitude and/or phase-shift modulations on the signals x,
the signals x are then amplified by power amplifiers before reaching the antennas.

The power amplifiers come into play at the very last moment, just before the antennas. This means that the signals are low power everywhere before power amplifiers, and thus also at the splitter level.

Random signal generators are widely available in any programming language, such as C++, Matlab, etc. Alternatively, low-level solutions are based on the use of shift registers, such as the pseudo-noise random generators used in direct-sequence spread-spectrum technologies.

Alternatively, the signals x may be directly digitally synthesised, then amplified by power amplifiers before reaching the antennas.

The digital solution should be quite low cost, while providing a simpler context for the user.

In accordance with the invention, there is also provided a system for generation of statistically uniform field distribution inside a test volume of a reverberation chamber, said system comprising:
analogue components or processing unit to generate complex independent and identically distributed random signals x,
modulators or processing unit to filter signals x through a passage matrix P according to a linear transformation in order to determine correlated excitation signals “a” by “a”=Px, determined from a complex transfer function H between the test volume and the antennas; and P is constructed such that E=HPx where E is independent and identically distributed, and
antennas of the reverberation chamber to receive simultaneously correlated excitation signals “a” and generating the field E.

For the purpose of illustrating the invention, there is shown in the drawings a form that is presently preferred; it is understood, however, that this invention is not limited to the proposed setup and devices.

FIG. 1 is a schematic view illustrating a system for creating electromagnetic modes inside a reverberation chamber by using two wire lines according to prior art,

FIG. 2 is a schematic view illustrating a system for modifying boundary conditions inside a reverberation chamber by using several antennas according to prior art,

FIG. 3 is a schematic view illustrating a system for modifying boundary conditions inside a reverberation chamber by using additional resonant antennas according to prior art,

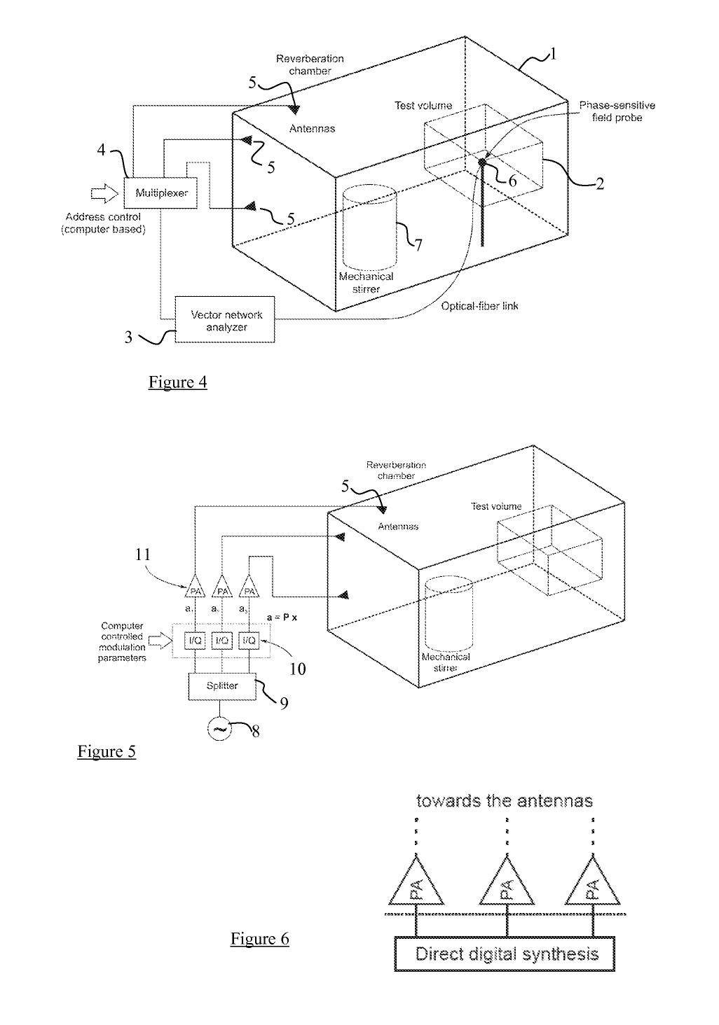

FIG. 4 is a schematic view illustrating a system for generating a uniformly distributed field inside a reverberation chamber during a calibration phase according to the present invention,

FIG. 5 is a schematic view illustrating a system for generating a uniformly distributed field inside a reverberation chamber during an operational phase according to the present invention,

FIG. 6 is a schematic view illustrating a direct digital synthesis of excitation signals.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents, and alternatives falling within the scope of the present invention as defined by the appended claims.

According to the modal theory of a cavity, the electric field generated within a cavity occupying a region of space Q can be linked to the excitation sources by means of the dyadic Green function of the medium Gₑₑ(r; r′), which is conveniently represented under a spectral expansion:

$${\underline{G}}_{ee} ( r , {r}^{′} ) = {\sum }_{n = 1}^{∞} \frac{{e}_{n} ( r ) {e}_{n} ( {r}^{′} )}{{k}^{2} - {k}_{n}^{2}} , \qquad ( 1 )$$

Where {eₙ(r)} are the normal modes of the cavity, i.e., the eigensolutions of Helmholtz equation, whereas {kₙ} are its eigenvalues, representing the frequencies of resonance of the cavity. In a general manner kₙ εC; in the context of reverberating cavities, the imaginary part of {kₙ} can be assumed to be much smaller than their real part, because of weakly lossy materials.

The electric field generated by electric sources J(r) is thus given by

$$E ( r ) = {\int }_{Ω}^{ } {\underline{G}}_{ee} ( r , {r}^{′} ) \cdot J ( {r}^{′} ) {d}^{3} {r}^{′} , \qquad ( 2 )$$

where only sources represented by electric current distributions have been considered, without any loss of generality. It is convenient to write (2) as

$$\begin{matrix}E ( r ) = {\sum }_{n = 1}^{∞} \frac{{y}_{n} {e}_{n} ( {r}^{′} )}{{k}^{2} - {k}_{n}^{2}} , \\ with & ( 3 ) \\ {y}_{n} = {\int }_{Ω}^{ } {e}_{n} ( r ) \cdot J ( r ) {d}^{3} r , & ( 4 )\end{matrix}$$

the modal weights.

Most stirring techniques operate by modifying the boundaries of Ω, which leads to a modification of the normal modes {eₙ(r)} and, ultimately, of the modal weights {yₙ}, through (4). This twofold modification of the modal quantities is intended to provide a randomization of the field distribution within the MSRC. Such approach is effective only as long as these modifications are based on displacements (sources, scatterers, walls, stirrers, etc.) of the order of at least half a wavelength. In a similar manner, frequency stirring exploits the modification of resonant propagation paths as the working frequency is modified: again, this type of technique is effective only if these modifications account for a significant additional phase-shift, i.e., an incremental path length of a non-negligible fraction of wavelength.

The failure of these prior art techniques in the lower frequency range are therefore inevitable, since for a fixed absolute modification (e.g., a displacement), the corresponding electric modification (phase shift) will reduce as the frequency decreases. Still, these problems do not mean that the field cannot be modified. Looking more closely at (3), it appears that a direct modification of the modal weights could allow a non-negligible modification of the electric field distribution. But stirring techniques usually do not operate by a direct modification of the {yₙ}, but rather indirectly by affecting the normal modes {eₙ(r)}. As soon as this strategy fails, modal weights are no more readily accessible.

The present invention introduces a novel stirring technique allowing a direct modification of the modal weights, thus providing a much stronger field randomization even though no mechanical displacement is considered. It will be shown that by the same token the field statistics can be optimized in order to dramatically improve the field uniformity at lower frequencies. This technique may be named Multiple-Antenna Stirring (MAS).

Consider a cavity operating in its intermediate frequency region, where it is no more possible to assume wave-diffusive features, as those expected for a scattering-rich random medium. This condition requires the availability and accessibility of a large (ideally infinite) number of degrees of freedom. These are nothing else than the normal modes of the cavity.

The typical modal structure encountered in this case is actually even worse. In practice, even in the case where a non-negligible number of modes is available, it appears that just a few dominate the field distribution, with modal weights that are hardly modified, e.g., by changing the position of the sources or operating a mechanical stirrer.

What happens if we ponder the eventual advantages of using multiple sources by applying independent harmonic excitations to the antennas? Due to the existence of these dominant modes, the distributed excitation of the cavity cannot provide any improvement with respect to a single-case configuration, because all of these sources are mainly operating over the same few modes. As a result, field uniformity is hardly affected, and the only advantage is the fact that the total injected power Pᵢₙ is now distributed over Nₐ antennas.

Excitation signals, from the subspace defined by the normal modes that are actually controllable, are chosen in order to design excitation signals for a multiple-antenna setup, capable of exciting all of the available degrees of freedom with the same effectiveness. To this effect, we need the ability to observe them, hence the need for a priori information, typically in the shape of measurements. To this effect, it is a good idea to recall that in the framework of the IEC standard field uniformity is one of the most pressing figures of merit. Without discussing of the fine details of its definition, we can nevertheless say that it is based on measurements taken over the 8 corners of a parallelepiped defining a candidate for the test volume. Three field components (usually Cartesian) are measured over them, making a grand total of 24 field samples. These are then multiplied by the number of realization generated by a stirring technique.

For the purpose of the present invention, based on the idea of stirring only the modal weights, and not the modal distributions {eₙ(r)}, we just need to consider a single configuration. We can thus juxtapose the 24 scalar field samples into a vector E₂₄εC^{24×1}, and link them to the incident power waves {aₙ(r)} applied to the Nₐ antenna input ports

E₂₄=Ha; (5)

where a is the vector containing the antenna excitations and HεC^{24×Na} is a generalized transfer function, obtained from the original field measurements during the calibration phase of the static MSRC. The singular values of H are a direct measure of how strongly each mode is coupled to the excitation antennas.

The random excitation of the modes is not useful per se, unless done in such a way as to generate a field distribution appearing as a Gaussian random process, with statistical moments independent from the spatial position, at least over the test volume. This need can be formalized by considering the covariance matrix C_{E} of the random vector E₂₄, defined as

C_{E}=E[E₂₄E₂₄^{H}], (6)

where E[.] is the ensemble average operator. In order to ensure spatial uniformity of the field statistical moments, depolarization (or isotropy) and independence of the field samples, we shall require

C_{E}=E₀²1, (7)

with 1 the identity matrix and E₀² the variance of the field.

Inserting (5) into (6),

C_{E}=HCₐH^{H}, (8)

with Cₐ the covariance matrix of the excitation signals.

Therefore (7) requires solving

E₀²1=HCₐH^{H}, (9)

with respect to Cₐ, i.e., designing excitation signals correlated in such a way as to ensure a covariance matrix for the field samples proportional to the identity matrix. It is clear from (8) that the choice of using independent random excitations could not provide a solution, since the covariance matrix would be given by HH^{H}, which is unlikely to approximate an identity matrix, unless an infinite number of modes were available, since this is in contradiction with our starting point. We will rather apply a least-square approach, by multiplying at the left of (9) by H^{H} and at its right by H, which allows us to write

Cₐ=E₀²(H^{H}H)⁻¹, (10)

where the equal sign is to be intended as a least-square solution. This solution is consistent as long as the transfer functions between the excitation antennas and the positions at which the field samples were measured are linearly independent, i.e., non redundant. In order to reduce the spatial correlation, the position between each couple of antennas is for example superior to one wavelength away.

Random excitation signals obeying to (10) can be defined by first generating independent and identically distributed signals xεC^{Na×1}, and then filtering them through a passage matrix PεC^{Na×Na}, defined as

P=\sqrt{(H^{H}H)⁻¹}E₀²1=HCₐH^{H}, (11)

Yielding

a=Px. (12)

Hence, the best approximation of (7) will be

C_{E}=H(H^{H}H)⁻¹H^{H}, (13)

which is now a true equality. Since the rank of the excitation covariance matrix is bounded by Nₐ, the rank of C_{E} will follow suite. It is therefore impossible to perfectly solve (7) and a residual correlation and disparities will appear in practice. The mathematical meaning of (12) is to generate random excitations aligned to the singular vectors of H, allowing to excite with equal effectiveness all of the available degrees of freedom of the cavity.

Now, preferred embodiments will be disclosed in reference to FIGS. 4, 5 and 6.

In accordance with the preferred embodiment as depicted on FIG. 4, a calibration phase is illustrated. The reverberation chamber 1 contains a test volume 2 in which a device under test is intended to be arranged during the operational phase. The reverberation chamber may be submitted to an electromagnetic field, acoustic field, or others. During the calibration phase, the system comprises a vector network analyzer 3 which generates calibration signals to a multiplexer 4. A computer or a processing unit (not shown) controls the multiplexer in order to feed antennas 5, preferably eight antennas, by calibration signals.

The antennas are arranged inside the reverberation chamber, typically on the walls. A non-invasive probe 6 is moved over some positions and orientations (polarization) in the reverberation chamber, typically about eight points (total of 24 positions) as required by the International Standards IEC. Advantageously, the probe is a phase-sensitive field probe which is able to measure three field components. For each position of the probe, the antennas are excited one by one and the field generated at the location of the probe is recorded as data by an operating system via the vector network analyzer 3. The probe 6 is connected to the vector network analyzer by an optical fiber link. These data are organized in a matrix H, and combined so as to obtain a square matrix P bound to the initial matrix H via a pseudo-inversion procedure. H is the matrix of the transfer functions between the antenna input ports and the scalar field components of which the statistical intensity is to be controlled.

Before each measurement (set of measurements), it is advantageous to conduct a calibration phase of the reverberation chamber to obtain the data needed to calculate the matrix P. The present invention can easily be combined with standard methods to improve them. FIG. 4 also shows a mechanical stirrer 7 according to the prior art to specifically target high working frequency.

In accordance with the preferred embodiment as depicted on FIG. 5, an operational phase is illustrated for an analogue direct-excitation setup. The basic idea is to be capable of injecting same-frequency signals at the different antenna ports, but with different amplitudes and phase-shift angles. As the phase-shift angles are relative one to the other, they have a common reference, hence a master oscillator behaving as a clock, synchronizing all the excitation signals together.

One way of implementing this setup is depicted on FIG. 5, where an analogue solution is proposed. In this solution an oscillator or continuous generator 8 generates a signal at the working frequency, which is subsequently split by the splitter 9 into a number of derivations (identical carriers), corresponding to the number of source antennas.

Each slave signal feeds one antenna, passing through a modulator block 10 to determine excitation signal “a”, and through a power amplifier 11. The signal “a” is determined from the pre-configured matrix P and the signal “a” which is a random vector of iid random variables. “x” is computer generated and then multiplied by P by means of the modulator block 10. In fact, the modulator applies an amplitude and a phase shift to the carrier signal. The signal “x” may be considered as the different amplitudes and/or phase shifts applied.

The modulator block design strongly depends on the type of approach being used and in particular on the need of amplitude, phase-shift or both modulations. Considerations on the design of this part can be divided between simple modulation schemes such as pure phase shifts (blind random excitations) or more complex modulation schemes such as I/Q modulations (mode generation and optimal random excitations). The ADL5390-EVALZ modulator proposed by Analog Devices may be used as I/Q modulator.

The modulator is driven by a controller, more generally a personal computer, by means of computer controlled modulation parameters. They can be of digital or analogue nature, depending on the type of modulator (both are equally likely in microwave devices). The outputs of the different modulators appear as sine-wave harmonic signals of arbitrary amplitude and phase-shift angles. With such an embodiment, all components before the power amplifiers are low power and thus inexpensive.

On the other hand, all-digital solutions can be adopted, also known as direct digital synthesis (DDS) according to FIG. 6. As long as the working frequency stays below a few hundred MHz, the solution presented in FIG. 6 would yield a simpler layout, while simplifying the signal generation procedure. The idea is to directly generate the harmonic signals, rather than passing through a modulation phase. This can be done by means of arbitrary generator circuits, which in their simplest form are just digital to analogue converters (DAC). Currently available low-cost DAC can handle sampling frequencies as high as 250 MHz, for 10 bit words, for a few US dollars. An example of integrated solutions for DDS is AD9913/PCBZ, manufactured by Analog Devices.

In addition to the foregoing, the input ports of the antennas 5 are connected to devices capable of varying the phase and/or amplitude of a harmonic signal common type, which is then applied simultaneously to all antennas. According to the invention, a signal sequence pseudo-random, initially independent, identically distributed (iid), is generated. An ideal room is supposed to generate a field with these same characteristics, but if the room is not in an overmoded state, iid stimuli applied to the antennas can not generate a field with such characteristics. Hence the use of this matrix P, which multiplies the pseudo-random sequence to generate iid correlated sequences which are then applied to the various antennas. This pre-correlation ensures the generation of a field inside the chamber as close as possible to the ideal case.

The present invention allows reduction of the size of a reverberation chamber, which can be used at low frequencies.

The method according to the invention makes it possible to partially avoid the use of mechanical stirring, since it is then possible to generate pseudo-random distributions by combining excited modes. Indeed, these modes are directly excitable one by one. Complex signatures can be calculated to generate distributions of different fields, according to predefined pseudo-random patterns.

The invention comprises a stage of correlation of excitation signals. This permits to generate at predefined positions in the room fields according to an arbitrary statistical law. It is possible to cancel the correlation between the observed fields at different positions, thanks to the pre-correlation of excitation signals.

With the present invention, it is possible to ensure a quasi-ideal behaviour of a reverberation chamber whose LUF is limited by standard stirring techniques at 100 MHz, down to 20 MHz.

Numerous variations and modifications will become apparent to those skilled in the art once the above disclosure is fully appreciated. It is intended that the following claims be interpreted to embrace all such variations and modifications.

1. A method for generation of statistically uniform field distribution inside a test volume of a reverberation chamber by means of antennas, said method comprising:
generating complex independent and identically distributed random signals x;
filtering signals x through a passage matrix P according to a linear transformation in order to determine correlated excitation signals “a” by “a”=Px, P being a passage matrix determined from a complex transfer function H between the test volume and the antennas; and P is constructed such that E=HPx where E is independent and identically distributed; and
generating the field E by applying simultaneously correlated excitation signals “a” to several antennas of the reverberation chamber.

2. The method according to claim 1, characterized in that P is obtained from the following formulation:
P=\sqrt{(H^{H}H)⁻¹}, H^{H} being the Hermitian matrix of H.

3. The method according to claim 1, characterized in that P is obtained by numerical optimization of 1=HPP^{H}H^{H} with a constraint c applied to P.

4. The method according to claim 3, characterized in that:
$$c = {max}_{P} \frac{{‖ E ‖}^{2}}{{‖ a ‖}^{2}} ,$$
where ∥a∥ is the norm of the vector of the excitations and ∥E∥ the norm of the field samples.

5. The method according to claim 3, characterized in that:
$$c = {min}_{p} {σ}_{a}^{2} .$$

6. The method according to claim 1, characterized in that it further comprises a calibration phase wherein several measuring points are defined, and for each measuring point measurements are determined using all antennas in order to determine the complex transfer function H.

7. The method according to claim 6, characterized in that for each measuring point, three field components are measured.

8. The method according to claim 6, characterized in that eight measuring points defining the test volume are used for the determination of the complex transfer function.

9. The method according to claim 6, characterized in that the measurements are performed by means of phase sensitive probe.

10. The method according to claim 1, characterized in that at least two or four antennas are used.

11. The method according to claim 1, characterized in that as many antennas as measuring points are used.

12. The method according to claim 1, characterized in that the distance between antennas arranged in the reverberation chamber is superior or equal to λ/2, λ being the wavelength of the working frequency.

13. The method according to claim 1, characterized in that all signals x are of the same frequency which is the working frequency.

14. The method according to claim 1, characterized in that the step of generating complex independent and identically distributed random signals x comprises a step of generating a master signal at the working frequency which is subsequently split into all signals x;
the step of filtering signals x through a passage matrix P comprises the step of applying amplitude and/or phase-shift modulations on the signals x; and
the signals x are then amplified by power amplifiers before reaching the antennas.

15. The method according to claim 1, characterized in that the signals x are directly digitally synthesised, then amplified by power amplifiers before reaching the antennas.

16. A system for generation of statistically uniform field distribution inside a test volume of a reverberation chamber by means of antennas, said system comprising:
analogue components or processing unit to generate complex independent and identically distributed random signals x;
modulators or processing unit to filter signals x through a passage matrix P according to a linear transformation in order to determine correlated excitation signals “a” by “a”=Px, determined from a complex transfer function H between the test volume and the antennas; and P is constructed such that E=HPx where E is independent and identically distributed; and
antennas of the reverberation chamber to receive simultaneously correlated excitation signals “a” and generating the field E.

17. The system according to claim 16, wherein the modulators are I/Q modulators.
